(19) United States
(12) Patent Application Publication
(10) Pub. No.: US 2026/0261196 A1
(43) Pub. Date: Sep. 3, 2026

(54) RECTIFIER CIRCUIT, AND SEMICONDUCTOR DEVICE AND POWER SUPPLY DEVICE USING SAME

(71) Applicant: Minebea Power Semiconductor Device Inc., Hitachi-shi, Ibaraki (JP)

(72) Inventors: Yoshihiro MIWA, Tokyo (JP); Hiroyuki SHOJI, Tokyo (JP); Junichi SAKANO, Hitachi-shi (JP); Takahiro HIGUCHI, Hitachi-shi (JP); Tomoyuki UTSUMI, Hitachi-shi (JP)

(21) Appl. No.: 19/491,227

(22) PCT Filed: Feb. 16, 2024
(86) PCT No.: PCT/JP2024/005456

§ 371 Date: Dec. 8, 2025

(30) Foreign Application Priority Data
Jun. 26, 2023 (JP) 2023-104063

(51) Int. Cl. H02M 1/088; G01R 19/165; H02M 3/158

(52) U.S. Cl. CPC H02M 1/088; G01R 19/16576; H02M 3/1588

(57) ABSTRACT

A rectifier circuit is capable of setting, without using a current detection unit, the number of semiconductor switching elements to be turned on among a plurality of synchronous rectification semiconductor switching elements connected in parallel. The rectifier circuit causes a current to flow in one direction between an anode and a cathode through synchronous rectification. A plurality of semiconductor switching elements are connected in parallel between the anode and the cathode, and a plurality of drive circuits are included to drive the semiconductor switching elements. A control unit creates a control command signal for each drive circuit based on a voltage between main terminals of the semiconductor switching elements. The control unit sets, based on the voltage and during a synchronous rectification period, the number of semiconductor switching elements to be turned on, and generates an on-control command signal for the set number of drive circuits.

### TECHNICAL FIELD

The present invention relates to a rectifier circuit, and to a semiconductor device and a power supply device using the rectifier circuit.

### BACKGROUND ART

As rectifier circuits used in power supply devices to convert alternating current into direct current, diode rectifier circuits or synchronous rectifier circuits using MOSFETs have been used. In synchronous rectifier circuits, the MOSFETs do not have a built-in potential like that of diodes, and a forward current starts to rise from 0 V. Therefore, power loss is low. Accordingly, synchronous rectifier circuits are used in power supply devices that require reduced power loss, such as front-end power supplies.

As conventional technologies related to synchronous rectifier circuits, the technologies described in Patent Literature 1 and Patent Literature 2 are known.

In the technology described in Patent Literature 1, a control circuit and a MOSFET are mounted in a single package as a low-loss rectifier circuit used in an alternator. This rectifier circuit operates as a two-terminal semiconductor device having the function (rectification function) of causing a current to flow in one direction like a diode.

The rectifier circuit according to the technology described in Patent Literature 1 includes the control circuit having a comparator and a gate driver, a capacitor that supplies power to the control circuit, and the MOSFET.

The control circuit turns on and off the MOSFET using the gate driver in accordance with the voltage between the drain and source of the MOSFET detected by the comparator. The capacitor is charged by the voltage between the drain and source of the MOSFET when the MOSFET is turned off.

In the technology described in Patent Literature 2, a plurality of MOSFETs for synchronous rectification are connected in parallel. The number of MOSFETs to be turned on among the plurality of MOSFETS is set in accordance with the magnitude of the load current, that is, the rectified current, so as to reduce the total power loss.

### CITATION LIST

### Patent Literature

Patent Literature 1: Japanese Patent Application Publication No. 2015-116053
Patent Literature 2: Japanese Patent Application Publication No. 2010-213366

### SUMMARY OF INVENTION

### Technical Problem

When the control technology described in Patent Literature 2 is applied to the rectifier circuit described in Patent Literature 1, it is necessary to additionally provide a current detection unit for detecting a rectified current, that is, a shunt resistor for current detection and a transformer for current detection, and the like, which hinders the miniaturization and cost reduction of the rectifier circuit.

Therefore, the present invention provides a rectifier circuit capable of setting the number of semiconductor switching elements to be turned on without additionally providing a current detection unit, and a semiconductor device and a power supply device using the same.

### Solution to Problem

In order to solve the above problem, a rectifier circuit according to the present invention causes a current to flow in one direction between an anode and a cathode through synchronous rectification. The rectifier circuit includes: a plurality of semiconductor switching elements connected in parallel between the anode and the cathode; a plurality of drive circuits that drive the plurality of semiconductor switching elements; and a control unit that creates a control command signal for each of the plurality of drive circuits on a basis of a voltage between main terminals of the plurality of semiconductor switching elements. The control unit sets, on the basis of the voltage between the main terminals during a synchronous rectification period, the number of semiconductor switching elements to be turned on among the plurality of semiconductor switching elements, and generates an on-control command signal for the set number of drive circuits.

In order to solve the above problem, a semiconductor device according to the present invention includes: a rectifier circuit; and a semiconductor package incorporating the rectifier circuit. The rectifier circuit is the above rectifier circuit according to the present invention.

In order to solve the above problem, a semiconductor device according to the present invention includes: a bridge rectifier circuit including a plurality of rectifier circuits; and a semiconductor package incorporating the bridge rectifier circuit. Each of the plurality of rectifier circuits is the above rectifier circuit according to present invention.

In order to solve the above problem, a power supply device according to the present invention includes a rectifier circuit unit. The rectifier circuit unit includes the above rectifier circuit according to the present invention.

### Advantageous Effects of Invention

According to the present invention, the number of semiconductor switching elements to be turned on can be set without additionally providing a current detection unit.

Problems, configurations, and effects other than those described above will be apparent from the embodiments described below.

### BRIEF DESCRIPTION OF DRAWINGS

FIG. 1 is a circuit diagram illustrating the configuration of the rectifier circuit according to a first embodiment.

FIG. 2 is a circuit diagram illustrating the configuration of the comparison unit in the first embodiment.

FIG. 3 is a schematic circuit diagram illustrating an example of the configuration of retention circuits H1 and H2 (FIG. 2).

FIG. 4 is a current and voltage waveform diagram illustrating an example of the operation of the rectifier circuit according to the first embodiment.

FIG. 5 is a circuit diagram illustrating the configuration of the rectifier circuit according to a second embodiment.

FIG. 6 is a current and voltage waveform diagram similar to FIG. 4, illustrating an example of the operation of the rectifier circuit according to the second embodiment.

FIG. 7 is a circuit diagram illustrating the configuration of the semiconductor device according to a third embodiment.

FIG. 8 is a circuit diagram illustrating the configuration of the power supply device according to a fourth embodiment.

### DESCRIPTION OF EMBODIMENTS

With reference to the drawings, embodiments of the present invention will be described below on the basis of the following first to third embodiments.

In each figure, elements designated by the same reference numerals indicate the same elements or elements having similar functions.

### First Embodiment

FIG. 1 is a circuit diagram illustrating the configuration of the rectifier circuit according to a first embodiment of the present invention.

In the figure, symbols indicating currents and voltages (the accompanying arrows indicate directions), namely, Is, Vdsi (i=1, 2, 3: the same applies hereinafter), Vgsi, and Vc represent a rectified current, a voltage between the main terminals, that is, a voltage between the drain and source of MOSFET Qi, a voltage between the gate and source of MOSFET Qi, and a charging voltage of a capacitor C0, respectively. Note that these symbols are used as appropriate in the following description.

In the rectifier circuit according to the first embodiment, a plurality of (three in FIG. 1) MOSFETs Q1 to Q3 are connected in parallel between an anode (A) and a cathode (K) as semiconductor switching elements for synchronous rectification. The drains and sources of Q1 to Q3 are connected to the cathode (K) and the anode (A), respectively. 01 to Q3 are turned on and off by drive circuits GD1 to GD3, respectively. Q1 to Q3 are turned on during a rectification period (rectified current Is ≥0), that is, when the AC voltage applied between the anode (A) and the cathode (K) is in the forward direction.

In the first embodiment, enhancement-type n-channel MOSFETs are applied as Q1 to Q3.

Diodes D1 to D3 are connected in antiparallel to the MOSFETs Q1 to Q3, respectively. In the first embodiment, D1 to D3 are body diodes incorporated in the MOSFETs. Note that externally provided individual diodes may be used as D1 to D3.

A comparison unit COM is a control unit that generates on/off control command signals for GD1 to GD3.

As will be described later, the comparison unit COM sets the number of MOSFETs to be turned on among Q1 to Q3 on the basis of the voltage between the anode (A) and the cathode (K), that is, the voltage Vds between the drains and sources of the MOSFETs connected in parallel, and then generates on/off control command signals for GD1 to GD3 in accordance with the set number. GD1 to GD3 turn on and off each of Q1 to Q3, respectively, in accordance with the on/off control command signals from COM.

The capacitor C0 serves as a power supply for both GD1 to GD3 and COM. One end of C0 is connected to the anode (A). The other end of C0 is connected to the cathode (K) via a reverse-current prevention diode DR1. As a result, during a non-rectification period (rectified current Is=0), that is, when the AC voltage applied between the anode (A) and the cathode (K) is in the reverse direction, C0 is charged by the voltage applied between the anode (A) and the cathode (K). The charged C0 serves as the power supply for both GD1 to GD3 and COM. In other words, the rectifier circuit according to the first embodiment is self-powered.

Here, the operation of the comparison unit COM will be further described.

The comparison circuit COM generates an on-control command signal to turn on n (=1 to 3) MOSFETs, which can reduce the total power loss P of Q1, Q2, and Q3, on the basis of Vds during a rectification period in which the rectified current Is flows from the anode (A) to the cathode (K).

When the voltage between the drains and sources of the MOSFETS connected in parallel is denoted as Vds, the total power loss P of the n MOSFETs that are turned on is schematically expressed by Equation (1).

$$P = n \cdot {P}_{d} + a \cdot ( n \cdot {V ds}^{2} ) / {R}_{ON} \qquad ( 1 )$$

Pa represents driving loss per MOSFET, RON represents on-resistance per MOSFET, and a represents a coefficient based on a voltage waveform.

As indicated by Equation (1), P_{d} becomes dominant when Vds is small. Therefore, P decreases as the number of MOSFETs that are turned on is reduced. When Vds increases, the second term in Equation (1) becomes dominant. Therefore, P decreases as the number of MOSFETs that are turned on is increased. Therefore, in the first embodiment, the magnitude of Vds is determined during a synchronous rectification period, and then n (=1 to 3) MOSFETs that can decrease P are turned on in accordance with the determined Vds. As a result, the power loss of the rectifier circuit can be reduced.

In the first embodiment, when n=1, the comparison unit COM generates an on-control command for GD1 to turn on Q1. When n=2, the comparison unit COM generates an on-control command for GD1 and GD2 to turn on Q1 and Q2. When n=3, the comparison unit COM generates an on-control command for GD1, GD2, and GD3 to turn on Q1, Q2, and Q3.

Note that, in order to turn off MOSFETs other than those that are turned on, the comparison unit COM generates an off-control command signal for the drive circuits of the MOSFETs that are to be turned off.

During a rectification period in which n=1, that is, when Q1 is turned on and Q2 and Q3 are turned off, the comparison unit COM determines, on the basis of Vds, whether to set n=2. When it is determined that n=2, the comparison unit COM generates an on-control command signal for GD2. Furthermore, during a rectification period in which n=2, that is, when Q1 and Q2 are turned on and Q3 is turned off, the comparison unit COM determines, on the basis of Vds, whether to set n=1. When it is determined that n=1, the comparison unit COM generates an off-control command signal for GD2.

During a rectification period in which n=2, that is, when Q1 and Q2 are turned on and Q3 is turned off, the comparison unit COM determines, on the basis of Vds, whether P can be further reduced by setting n=3 instead of n=2. When it is determined that P can be reduced, the comparison unit COM generates an on-control command signal for GD3. Furthermore, in a rectification period in which n=3, that is, when Q1, Q2, and Q3 are turned on, the comparison unit COM determines, on the basis of Vds, whether P can be further reduced by setting n=2 instead of n=3. When it is determined that P can be reduced, the comparison unit COM generates an off-control command signal for GD3.

As described above, in order to reduce the total power loss P, the comparison unit COM switches the number n of MOSFETs to be turned on between 1 and 2, and between 2 and 3, on the basis of Vds during a rectification period. Note that the comparison unit COM determines the switching between the number n of MOSFETs to be turned on by comparing Vds during a rectification period with a specified threshold voltage.

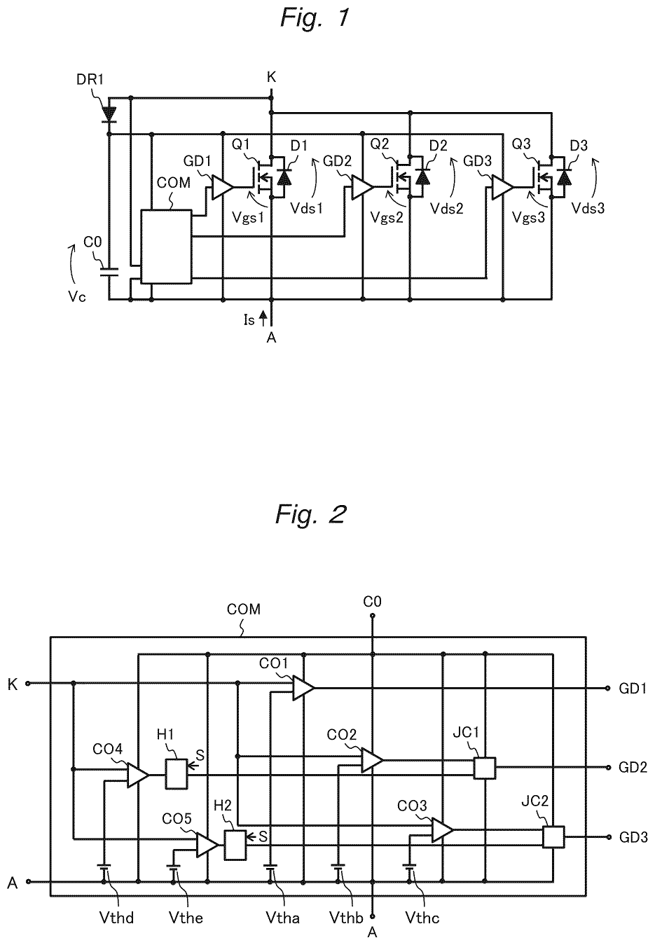

FIG. 2 is a circuit diagram illustrating the configuration of the comparison unit COM in the first embodiment (FIG. 1).

Note that the forward direction of the MOSFETs Q1 to Q3 is regarded as the positive voltage direction. Therefore, Vds≤0 during a rectification period.

The comparison unit COM includes comparison circuits CO1 to CO5, determination circuits JC1 and JC2, and retention circuits H1 and H2. Each of these circuits uses the charged capacitor C0 (FIG. 1) as a power supply.

The voltage between the anode (A) and cathode (K), that is, Vds, is input to the comparison circuits CO1 to CO5. In the comparison circuits CO1, CO2, CO3, CO4, and CO5, threshold voltages (<0) to be compared with Vds are set by reference voltage sources Vtha, Vthb, Vthc, Vthd, and Vthe, respectively. The comparison circuits CO1 to CO5 compare the magnitude relationship between Vds and the threshold voltages, and output, according to the comparison results, either a voltage signal at a high level (H) (hereinafter referred to as “voltage signal H”) or a voltage signal at a low level (L) (hereinafter referred to as “voltage signal L”). Note that, in the first embodiment, the voltage value of the voltage signal H is the power supply voltage value of the capacitor C0 (FIG. 1), and the voltage value of the voltage signal L is 0 V.

Note that each reference voltage source is generated using the capacitor CO (FIG. 1) and either a voltage divider or a zener diode.

In the following description, unless otherwise specified, Vds represents the voltage between the drain and the source during a rectification period, and Vds≤0. Accordingly, the value of the threshold voltage (Vth1, which will be described later) to be compared with Vds is also a negative value.

CO1 to CO3 compare the voltage between A and K, that is, Vds, with the threshold voltage Vth1. When it is determined that Vds is equal to or less than Vth1 (Vds≤Vth1, |Vds|≥|Vth1|), CO1 to CO3 output the voltage signal H. Furthermore, CO1 to CO3 compare Vds with a threshold voltage Vth2. When it is determined that Vds is equal to or greater than the Vth2 (Vds≥Vth2, |Vds|≤|Vth2|), CO1 to CO3 output the voltage signal L (0 V). That is, the reference voltage sources Vtha, Vthb, and Vthc correspond to the two threshold voltages Vth1 and Vth2.

As a result, CO1 to CO3 output the voltage signal H during the rectification period and output the voltage signal L outside the rectification period. That is, CO1 to CO3 determine whether the present time is within the rectification period.

In CO1 to CO3, Vth1 represents the threshold voltage when the MOSFETs Q1 to Q3 are turned off, and Vth2 represents the threshold voltage when the MOSFETs Q1 to Q3 are turned on. That is, in CO1 to CO3, the threshold voltages have hysteresis. For example, CO1 to C03 are each composed of a hysteresis comparator.

The threshold voltages Vth1 and Vth2 may have the same value, or may have two different values that satisfy Vth1<Vth2. In the latter case, it is possible to suppress chattering in which Q1 is repeatedly turned on and off in a short period.

CO1 outputs the voltage signal H and the voltage signal L to the drive circuit GD1 as an on-control command signal and an off-control command signal, respectively. As a result, Q1 is turned on at the start of the rectification period, is kept in an on-state during the rectification period, and is turned off at the end of the rectification period. That is, Q1 is turned on in each rectification period. Accordingly, in the first embodiment, the number n of MOSFETs to be turned on during the rectification period is at least 1.

CO4 determines the switching of the number n of MOSFETs to be turned on from 1 to 2 and from 2 to 1, respectively, using threshold voltages Vthd1 and Vthd2 for determining the switching.

When only Q1 among Q1 to Q3 is turned on, CO4 compares the voltage between A and K, that is, Vds, with the threshold voltage Vthd1. When it is determined that Vds is equal to or less than Vthd1 (Vds≤Vthd1, |Vds|≥|Vthd1|), CO4 outputs the voltage signal H. In this manner, CO4 determines the switching of n from 1 to 2. By turning on Q2 on the basis of this voltage signal H, n is switched from 1 to 2.

When it is determined that Vds is greater than Vthd1 (Vds>Vthd1, | Vds|<| Vthd1|), CO4 outputs the voltage signal L.

Furthermore, when Q1 and Q2 among Q1 to Q3 are turned on and Q3 is turned off, CO4 compares the voltage between A and K, that is, Vds, with the threshold voltage Vthd2. When it is determined that Vds is equal to or greater than Vthd2 (Vds≥Vthd2, |Vds|≤|Vthd2|), CO4 outputs the voltage signal L. In this manner, CO4 determines the switching of n from 2 to 1. By turning off Q2 on the basis of this voltage signal L, n is switched from 2 to 1.

When it is determined that Vds is smaller than Vthd2 (Vds<Vthd2, | Vds|>| Vthd2|), CO4 outputs the voltage signal H.

CO5 determines the switching of the number n of MOSFETs to be turned on from 2 to 3 and from 3 to 2, respectively, using threshold voltages Vthe1 and Vthe2 for determining the switching.

When Q1 and 02 among Q1 to Q3 are turned on and Q3 is turned off, CO5 compares the voltage between A and K, that is, Vds, with the threshold voltage Vthe1. When it is determined that Vds is equal to or less than Vthe1 (Vds≤Vthe1, |Vds|≥|Vthe1|), CO5 outputs the voltage signal H. In this manner, CO5 determines the switching of n from 2 to 3. By turning on Q3 on the basis of this voltage signal H, n is switched from 2 to 3.

When it is determined that Vds is greater than Vthe1 (Vds>Vthe1, | Vds|<| Vthe1|), CO5 outputs the voltage signal L.

Furthermore, when all of Q1 to Q3 are turned on, CO5 compares the voltage between A and K, that is, Vds, with the threshold voltage Vthe2. When it is determined that Vds is equal to or greater than Vthe2 (Vds≥ Vthe2, |Vds|≤|Vthe2|), CO5 outputs the voltage signal L. In this manner, CO5 determines the switching of n from 3 to 2. By turning off Q3 on the basis of this voltage signal L, n is switched from 3 to 2.

When it is determined that Vds is smaller than Vthe2 (Vds<Vthe2, | Vds|>| Vthe2|), CO5 outputs the voltage signal H.

Outside the rectification period, Vds≥0. Therefore, because Vds is greater than the above-described threshold voltages (Vthd1, Vthd2, Vthe1, and Vthe2<0), both CO4 and CO5 output the voltage signal L. As a result, Q2 and Q3 are turned off. Accordingly, outside the rectification period, all the MOSFETs of Q1 to Q3 are turned off.

Note that CO4 and CO5 are each composed of a hysteresis comparator, similarly to, for example, CO1 to CO3.

In the first embodiment, the determination results output by CO4 and CO5 as described above are reflected in the next rectification period after the rectification period in which CO4 output this voltage signal. That is, when CO4 and CO5 determine to switch the number of MOSFETs to be turned on, the number is switched in the next rectification period after the rectification period in which the determination was made. For this purpose, the comparison unit COM includes the retention circuits H1 and H2.

The retention circuit H1 retains the determination result of CO4 as described above, that is, either the voltage signal H or the voltage signal L output by CO4. The retention circuit H1 outputs the retained voltage signal to the determination circuit JC1 in the next rectification period after the rectification period in which CO4 output this voltage signal.

The retention circuit H2 retains the determination result of CO5 as described above, that is, either the voltage signal H or the voltage signal L output by CO5. The retention circuit H2 outputs the retained voltage signal to the determination circuit JC2 in the next rectification period after the rectification period in which CO5 output this voltage signal.

The determination circuit JC1 outputs the voltage signal H when it receives the voltage signal H from the retention circuit H1 and the voltage signal H from CO2, which indicates that the present time is within the rectification period. The output voltage signal H is input to the drive circuit GD2 as an on-control command signal. GD2 turns on Q2 in accordance with the input on-control command signal.

The determination circuit JC1 outputs the voltage signal L when it receives the voltage signal L from at least one of the retention circuit H1 or CO2. The output voltage signal L is input to the drive circuit GD2 as an off-control command signal. The drive circuit GD2 turns off Q2 in accordance with the input on-control command signal.

The determination circuit JC2 outputs the voltage signal H when it receives the voltage signal H from the retention circuit H2 and the voltage signal H from CO3, which indicates that the present time is within the rectification period. The output voltage signal H is input to the drive circuit GD3 as an on-control command signal. GD3 turns on Q3 in accordance with the input on-control command signal.

The determination circuit JC2 outputs the voltage signal L when it receives the voltage signal L from at least one of the retention circuit H2 or CO3. The output voltage signal L is input to the drive circuit GD3 as an off-control command signal. The drive circuit GD3 turns off Q3 in accordance with the input on-control command signal.

The determination circuits JC1 and JC2 are each composed of, for example, a logical conjunction (AND) gate circuit.

According to the determination circuits JC1 and JC2, an on/off control command signal can be reliably generated in accordance with the determination results of the CO4 and CO5 during synchronous rectification in the rectification period. Accordingly, n can be reliably set on the basis of Vds.

Note that, instead of CO2 and CO3, the flow of an on-gate current in the gate of Q1 may be detected to determine whether the present time is within the synchronous rectification period, and the resulting determination result may be input to the JC1 and JC2.

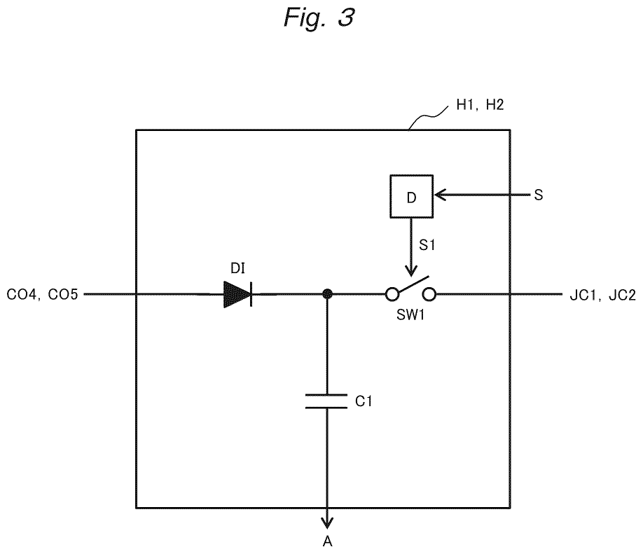

FIG. 3 is a schematic circuit diagram illustrating an example of the configuration of the retention circuits H1 and H2 (FIG. 2).

The retention circuits in the first embodiment retain the determination results of the comparison circuits by means of the charging and discharging of the capacitor.

The retention circuits (H1 and H2) include a capacitor C1 that retains the voltage signals output by the comparison circuits (CO4 and CO5), and a switch SW1 that is turned on to output the voltage signals retained in the capacitor C1 to the determination circuits (JC1 and JC2).

One end of the capacitor C1 is connected to the outputs of the comparison circuits (CO4 and CO5) via a reverse-current prevention diode DI. The anode and cathode of the reverse-current prevention diode DI are connected to the outputs of the comparison circuits (CO4 and CO5) and to one end of the capacitor C1, respectively. The other end of the capacitor C1 is connected to the anode (A) of the rectifier circuit (FIG. 1). One end of the capacitor C1 is connected to the inputs of the determination circuits (JC1 and JC2) via the switch SW1.

In the first embodiment, the switch SW1 is composed of a semiconductor switching element, for example, a MOSFET. The switch SW1 is turned on and off by a drive signal S1 from a drive circuit D. The drive circuit D generates the drive signal S1 in accordance with a command signal S. Note that the drive circuit D uses the charged capacitor C0 (see FIG. 1) as a power supply.

When the drive circuit D receives the voltage signal H output by the comparison circuits (CO4 and CO5) as the command signal S, it generates an off-drive signal as S1 and turns off SW1. At this time, the capacitor C1 retains the voltage signal H. In addition, the voltage signal H is not input to the determination circuits (JC1 and JC2).

When the drive circuit D receives, as the command signal S, the voltage signal L output by any of CO1 to CO3, which outputs the voltage signal H, it generates an on-drive signal as S1 and turns on SW1. As a result, the voltage signal H retained in the capacitor C1 is input to the determination circuits (JC1 and JC2) in the next rectification period after the rectification period in which the voltage signal H was retained in the capacitor C1.

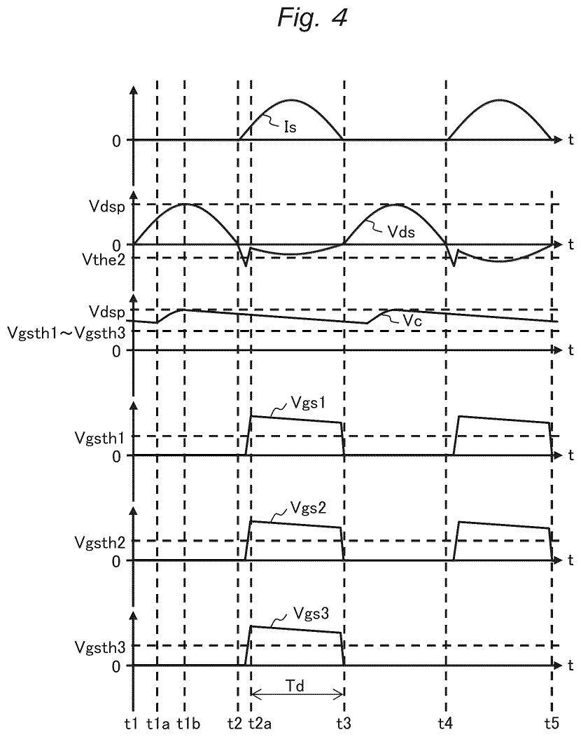

FIG. 4 is a current and voltage waveform diagram illustrating an example of the operation of the rectifier circuit according to the first embodiment.

In the operation example of FIG. 4, the number n of MOSFETs to be turned on is switched from 3 to 2.

A sinusoidal AC voltage is input to the series-connected circuit of the rectifier circuit (FIG. 1) and a resistive load.

The waveforms illustrated in FIG. 4, from the top, are: the rectified current Is; the voltage between the anode (A) and cathode (K) of the rectifier circuit, that is, the voltage Vds between the drains and sources of the MOSFETS Q1 to Q3 connected in parallel (with the forward direction of Q1 to Q2 taken as positive); the voltage Vc of the capacitor C0; and the voltages Vgs1 to Vgs3 between the gates and sources of Q1 to Q3. Vgsth1 to Vgsth3 represent the gate threshold voltages of Q1 to Q3, respectively.

Vdsp represents the peak value of the AC voltage. Because C0 is charged by the voltage of a half-sine wave in the non-rectification period, the maximum value of Vc becomes Vdsp. Note that although Vc gradually decreases with discharging, it ensures a greater value than Vgsth1 to Vgsth3 during the operation of the rectifier circuit as illustrated in FIG. 4.

In the operation example illustrated in FIG. 4, during the period from the time at which the commutation of the rectified current Is from the diodes D1 to D3 to the on-resistance paths of the MOSFETs Q1 to Q3 is completed, that is, time t2a at which diode rectification is transitioned to synchronous rectification, to time t3 at which Is becomes 0, Vds caused by the on-resistance (Ron) of Q1 to Q3 and the rectified current Is is compared with the threshold voltage Vthe2 described above. As described above, Vthe2 is the voltage threshold for determining switching from n=3 to n=2. As illustrated in FIG. 4, because Vds≥ Vthe2 in the synchronous rectification period (t2a to t3), switching to n=2 is performed in the next rectification period (t4 to t5).

As described above, because n is set on the basis of Vds according to the first embodiment, n can be set so as to reduce the total power loss P without providing a current detection unit.

Note that in the first embodiment, the determination result of the comparison circuit is reflected in the setting of n in the next rectification period after the rectification period in which the determination was made. However, the present invention is not limited to this, and n may be switched in the rectification period in which the determination was made. In this case, the retention circuits H1 and H2 (FIG. 2) can be omitted.

### Second Embodiment

A second embodiment according to the present invention will be described below, mainly focusing on points that differ from the first embodiment.

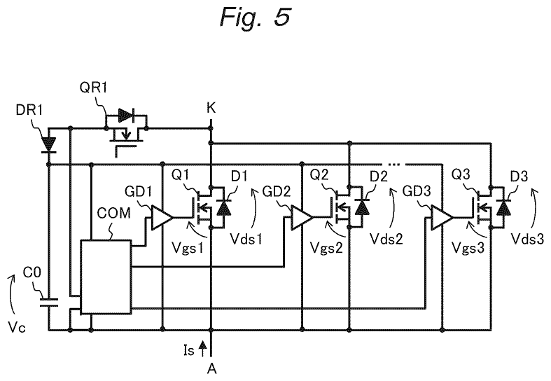

FIG. 5 is a circuit diagram illustrating the configuration of the rectifier circuit according to the second embodiment of the present invention.

In the second embodiment, the anode of the reverse-current prevention diode DR1 is connected to the cathode (K) of the rectifier circuit via a MOSFET QR1, a semiconductor switch. The source and drain of QR1 are connected to the anode of DR1 and the cathode (K) of the rectifier circuit, respectively.

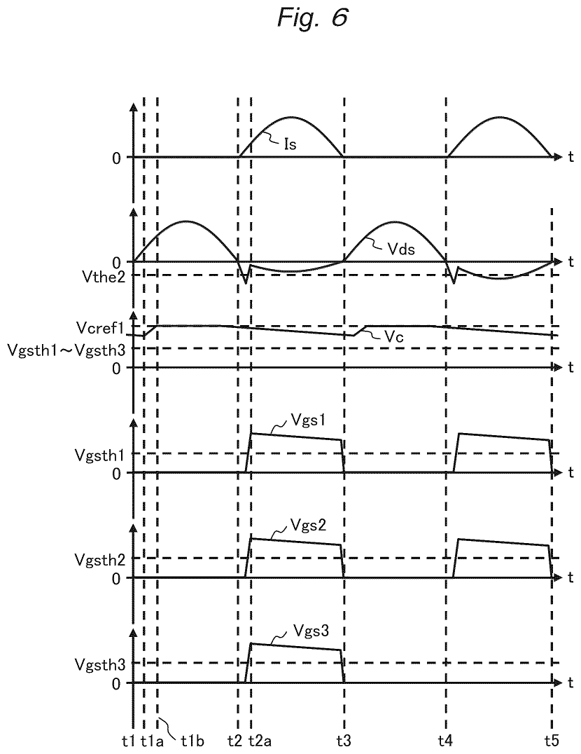

FIG. 6 is a current and voltage waveform diagram similar to FIG. 4, illustrating an example of the operation of the rectifier circuit according to the second embodiment.

The capacitor CO is charged to a target voltage Vcref. At this time, QR1 is controlled to turn on and off so that the voltage Vc of C0 does not exceed Vcref, thereby limiting the current from the cathode K to the capacitor C0 of the rectifier circuit.

According to the second embodiment, the rated voltages of the comparison unit COM, the drive circuits GD1 to GD3, and the capacitor C0 can be set lower than that of the rectifier circuit. As a result, the rated voltage of the rectifier circuit is not limited by those of the comparison unit COM, the drive circuits GD1 to GD3, and the capacitor C0, facilitating the high-voltage operation of the rectifier circuit.

### Third Embodiment

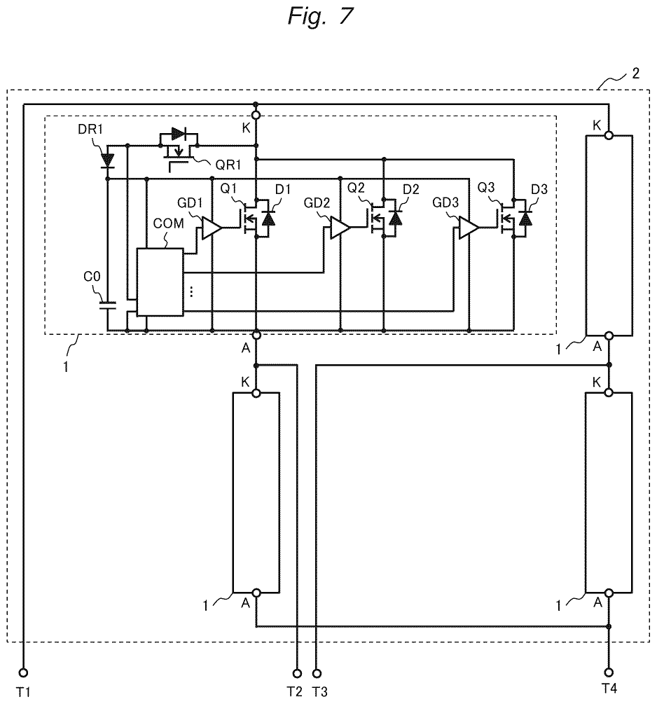

FIG. 7 is a circuit diagram illustrating the configuration of the semiconductor device according to a third embodiment of the present invention.

As illustrated in FIG. 7, in the third embodiment, four rectifier circuits 1 are incorporated in a semiconductor package 2 as semiconductor circuits. The rectifier circuits 1 are based on the rectifier circuit according to the second embodiment (FIG. 5). The four rectifier circuits 1 form a single-phase bridge rectifier circuit.

In the semiconductor package 2, each rectifier circuit 1 is sealed with a molding resin, a resin case, or the like, and a pair of AC terminals T2 and T3 and a pair of DC terminals T1 and T4 of the single-phase bridge rectifier circuit are exposed on the outer surface of the resin that seals the four rectifier circuits 1.

According to the third embodiment, synchronous rectifier circuits can be easily applied to the single-phase bridge rectifier circuit in place of the rectifier diodes, thereby reducing the losses of the single-phase bridge rectifier circuit and an electric or electronic device including the single-phase bridge rectifier circuit.

In the semiconductor device according to the third embodiment, the AC terminals T2 and T3 and the DC terminals T1 and T4 in the semiconductor package 2 are arranged to match the packaged diode bridge, thereby providing compatibility with the diode bridge. Furthermore, the semiconductor device according to the third embodiment operates, while using synchronous rectification, as a four-terminal rectifier element, similarly to a single-phase diode bridge. Therefore, the man-hours for the design and implementation of an electric or electronic device including a full-wave rectifier circuit unit can be reduced.

Note that the rectifier circuits 1 may be based on the rectifier circuit according to the first embodiment. Furthermore, six rectifier circuits based on any of the first and second embodiments can be used to form a three-phase bridge rectifier circuit.

In this case, three AC terminals for three phases and a pair of DC terminals are exposed on the outer surface of the resin that seals the six rectifier circuits.

### Fourth Embodiment

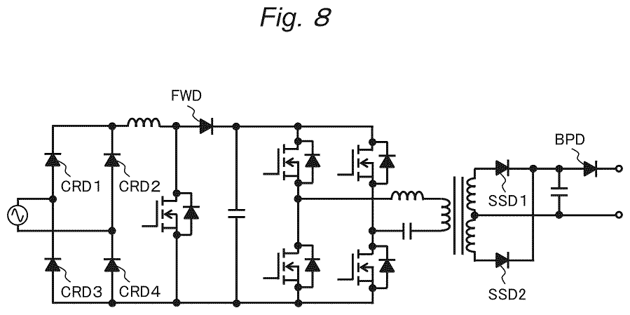

FIG. 8 is a circuit diagram illustrating the configuration of the power supply device according to a fourth embodiment of the present invention.

The power supply device illustrated in FIG. 8 converts AC power from a commercial AC power supply into DC power of a desired voltage and outputs the DC power.

The rectifier circuit according to any of the first and second embodiments or the semiconductor device according to the third embodiment is applied to at least any one of the rectifier elements denoted by diode circuit symbols in FIG. 8, that is: rectifier elements CRD1 to CRD4 that form a bridge rectifier circuit for rectifying an AC voltage of a commercial AC voltage; a reflux rectifier element FWD in a chopper circuit unit; rectifier elements SSD1 and SSD2 that form a rectifier circuit unit for converting AC power output from an inverter circuit unit via a transformer into a DC voltage of a desired level; and a reverse-current prevention rectifier element BPD. Note that the rectifier elements CRD1 to CRD4 may be implemented using the single-phase bridge rectifier circuit according to the third embodiment.

Note that in FIG. 8, the rectifier elements connected in parallel with the MOSFETs are parasitic diodes (body diodes) of the MOSFETs. Furthermore, if all the rectifier elements in FIG. 8 are diodes, the circuit configuration of the power supply device in FIG. 8 is a known circuit configuration.

According to the fourth embodiment, the power loss of the power supply device can be reduced. Note that the power supply device according to the fourth embodiment is suitable for a front-end power supply that requires high efficiency.

Note that the rectifier circuits according to the first and second embodiments and the semiconductor device according to the third embodiment are not limited to front-end power supplies and can be applied to various power supply devices that include a rectifier circuit unit.

Note that the present invention is not limited to the above embodiments and includes various modified examples. For example, the above embodiments are described in detail for the purpose of facilitating understanding of the present invention, and do not necessarily include all the configurations described above. Furthermore, a part of the configuration of one embodiment may be replaced with that of another embodiment, or the configuration of one embodiment may be added to that of another embodiment. Furthermore, with respect to a part of the configuration of each embodiment, deletion, addition of other configurations, or replacement with other configurations is also possible.

For example, the MOSFETs are not limited to n-channel types but may be p-channel types. Furthermore, the MOSFETs are not limited to enhancement types but may also be depletion types. Instead of the MOSFETs, other unipolar semiconductor switching elements (such as junction FETs or static induction transistors) may be applied. The semiconductor material for the semiconductor switching elements is not limited to silicon (Si) but may be a wide band gap semiconductor, such as silicon carbide (Sic).

Furthermore, the comparison unit COM may be configured by software using a control device such as a microcomputer.

### REFERENCE SIGNS LIST

1 Rectifier circuit
2 Semiconductor package
T1, T4 DC terminal
T2, T3 AC terminal

1. A rectifier circuit that causes a current to flow in one direction between an anode and a cathode through synchronous rectification, the rectifier circuit comprising:
a plurality of semiconductor switching elements connected in parallel between the anode and the cathode;
a plurality of drive circuits that drive the plurality of semiconductor switching elements; and
a control unit that creates a control command signal for each of the plurality of drive circuits on a basis of a voltage between main terminals of the plurality of semiconductor switching elements,
wherein
the control unit sets, on the basis of the voltage between the main terminals during a synchronous rectification period, the number of semiconductor switching elements to be turned on among the plurality of semiconductor switching elements, and generates the control command signal for the drive circuits in accordance with the set number.

2. The rectifier circuit according to claim 1, wherein
the control unit retains the control command signal and outputs the retained control command signal to the drive circuits during a next synchronous rectification period.

3. The rectifier circuit according to claim 1, wherein
the control unit compares the voltage between the main terminals with a specified threshold voltage, and sets the number on a basis of a comparison result.

4. The rectifier circuit according to claim 3, wherein
the threshold voltage is preset on a basis of total power loss of the plurality of semiconductor switching elements.

5. The rectifier circuit according to claim 1, wherein
the control unit determines whether to increase the number by 1 or decrease the number by 1.

6. The rectifier circuit according to claim 5, wherein
the control unit compares the voltage between the main terminals with a specified first threshold voltage and a second threshold voltage, and determines whether to increase the number by 1 or decrease the number by 1 on a basis of a comparison result.

7. The rectifier circuit according to claim 1, wherein
the control unit determines the synchronous rectification period on the basis of the voltage between the main terminals.

8. The rectifier circuit according to claim 1, wherein
the control unit determines the synchronous rectification period on a basis of a drive current flowing from the drive circuits to the semiconductor switching elements.

9. The rectifier circuit according to claim 1, comprising
a capacitor connected between the anode and the cathode, wherein
the plurality of drive circuits and the control unit use the capacitor as a power supply.

10. The rectifier circuit according to claim 9, wherein
one end of the capacitor is connected to the cathode via a reverse-current prevention diode.

11. The rectifier circuit according to claim 9, wherein
one end of the capacitor is connected to the cathode via a series circuit of a reverse-current prevention diode and a semiconductor switch.

12. A semiconductor device comprising:
a rectifier circuit; and
a semiconductor package incorporating the rectifier circuit,
wherein
the rectifier circuit is the rectifier circuit according to claim 1.

13. A semiconductor device comprising:
a bridge rectifier circuit including a plurality of rectifier circuits; and
a semiconductor package incorporating the bridge rectifier circuit,
wherein
each of the plurality of rectifier circuits is the rectifier circuit according to claim 1.

14. A power supply device comprising a rectifier circuit unit, wherein
the rectifier circuit unit includes the rectifier circuit according to claim 1.
